(19) United States
(12) Patent Application Publication
(10) Pub. No.: US 2011/0308606 A1
(43) Pub. Date: Dec. 22, 2011

(54) SOLAR CELL OF IMPROVED PHOTO-UTILIZATION EFFICIENCY

(76) Inventor: Feng-Chien Hsieh, Houli Township (TW)

(21) Appl. No.: 12/816,538

(22) Filed: Jun. 16, 2010

(51) Int. Cl. H01L 31/00

(52) U.S. Cl. 136/258; 136/259

(57) ABSTRACT

The present invention relates to a solar cell having a structure of improved photo-utilization efficiency. The solar cell comprises a transparent texture layer, a transparent conductive layer, a photoelectric conversion layer and a back electrode layer and a substrate under the back electrode layer stacked in a sequence from an incident light side. A laser scribing of module process is performed in the transparent conductive layer, the photoelectric conversion layer and the back electrode layer so as to form a laser scribing region and a photoelectric conversion active region where the transparent texture layer is formed of an angular or arc surface shape and has a concave portion opposite to the laser scribing region. The laser scribing region is provided to guide the incident light to concentrate on the photoelectric conversion active region.

### FIELD OF THE INVENTION

The present invention relates to a solar cell, and more particularly to a solar cell having enhanced photoelectric conversion efficiency by increasing photo-utilization rate in a semiconductor layer of the solar cell.

### DESCRIPTION OF PRIOR ART

A solar cell is produced as a photoelectric conversion device by means of utilizing photovoltaic effect to enable conversion of photon energy in the semiconductor layer of the solar cell received from an incident light so as to generate an electronic voltage and current. Solar cell distinguished by its material in the semiconductor layer can be monocrystalline silicon solar cells, polycrystalline silicon solar cells, or amorphous silicon solar cells. Besides, a variety of compounds used in the semiconductor layer of the solar cell includes a III-V group like gallium arsenide (GaAs), indium phosphide (InP), gallium indium phosphide (InGaP), a II-VI group like cadium telluride (CdTe), and a I-III-VI group like Cu(In,Ga)Se2.

The photo-absorption effect of the semiconductor layer of the solar cell determines whether the solar cell is good or not in the photoelectric conversion efficiency. Different angle of the incident light or different degree of light reflection will cause an impact on the photo-absorption of the solar cell into the electric energy. Besides, an invalid region produced by laser scribing will cause the effect of bad photo-absorption in the semiconductor layer so as to lead to optical loss of the solar cell. Besides, the light path is a key factor of determining the photoelectric conversion efficiency after the light passed to the solar cell. The electric current efficiency of the solar cell can be improved by means of reducing the light reflection or increasing the light path (or light intensity), thereby improving the photoelectric conversion efficiency. For example, the problem of poor photoelectric conversion can be resolved by texturing or roughening the incident-side surface of a cover glass to cause a “bended light” to cross through the mask region disposed under upper electrodes and then to enter the silicon-based solar cell. However, the resolution disclosed by the prior arts still limit the photoelectric conversion efficiency of the silicon-based solar cell. Therefore, a need exists for providing a solar cell with high absorption efficiency particularly in the semiconductor layer.

### SUMMARY OF THE INVENTION

In light of the aforesaid problems, a solar cell with a structure of improved photo-utilization efficiency has been disclosed in the invention. The solar cell configures a transparent texture layer to guide the incident light to concentrate on the photoelectric conversion active region, thereby increasing the photo-absorption in the semiconductor layer and further achieving the purpose of better photoelectric conversion.

In order to overcome the aforementioned shortcomings, the present invention provides a solar cell that comprises a transparent texture layer, a transparent conductive layer, a photoelectric conversion layer, a back electrode layer and a substrate stacked in a sequence from an incident light side. The transparent conductive layer, the photoelectric conversion layer and the back electrode layer are being scribed by a module process to form a laser scribing region and a photoelectric conversion active region. The transparent texture layer has an angular or arc surface, and a concave portion opposite to the laser scribing region so as to concentrate the incident light on the photoelectric conversion active region. The solar cell is further provided with an area ratio of the laser scribing region to the laser scribing region plus the photoelectric conversion active region so that the area ratio has a value of between 0.08 and 0.17.

Besides, the transparent texture layer is a cover glass, or a transparent glass substrate that is selected from the group consisting of soda lime glass (SLG), low iron class and alkali free glass. The photoelectric conversion layer comprises a buffer layer and an absorption layer so as to form a p-n type composite structure. The absorption layer is formed of a material selected from a group I-III-VI compound such as Cu(In,Ga)Se2 or CIGS, CuInSe2 or CIS, or Ag(In,Ga)Se2 or AIGS. The buffer layer is formed of a material selected from a group II-VI compound such as cadmium sulfide (CdS), or zinc sulfide (ZnS). The substrate is formed of a material selected from the group consisting of glass, quartz, transparent plastics, transparent polymer, flexible metals and flexible plastics.

The present invention provides another solar cell that comprises a transparent texture layer, a transparent conductive layer, a photoelectric conversion layer and a back electrode layer stacked in a sequence from an incident light side. The transparent conductive layer, the photoelectric conversion layer and the back electrode layer are being scribed by a module process to form a laser scribing region and a photoelectric conversion active region. The transparent texture layer has an angular or arc surface, and a concave portion opposite to the laser scribing region so as to concentrate the incident light on the photoelectric conversion active region. The solar cell is further provided with an area ratio of the laser scribing region to the laser scribing region plus the photoelectric conversion active region so that the area ratio has a value of between 0.08 and 0.17.

Besides, the transparent texture layer is a transparent glass substrate that is selected from the group consisting of soda lime glass (SLG), low iron class and alkali free glass. The photoelectric conversion layer has a material selected from the group consisting of amorphous silicon (a-Si), polycrystalline silicon (poly-Si), microcrystalline silicon (mc-Si) and microcrystalline silicon germanium (mc-SiGe), or selected from a II-VI group compound such as cadmium sulfide (CdS) or cadium telluride (CdTe).

The present invention provides a solar cell that comprises a plurality of silicon wafers spaced therebetween, and each of silicon wafers comprises a front electrode layer, an anti-reflectance layer, a photoelectric conversion layer and a back electrode layer stacked in a sequence from an incident light side. Each silicon wafer further comprises a transparent texture layer formed thereon. The transparent texture layer has an angular or arc surface, and a concave portion opposite to a gap spaced between the plurality of silicon wafers so as to concentrate the incident light on each silicon wafer.

Besides, the transparent texture layer is a transparent glass substrate that is selected from the group consisting of soda lime glass (SLG), low iron class and alkali free glass. The photoelectric conversion layer has a material selected from the group consisting of amorphous silicon (a-Si), polycrystalline silicon (poly-Si), microcrystalline silicon (mc-Si) and microcrystalline silicon germanium (mc-SiGe).

Besides, the transparent conductive layer of the solar cell can be one of fluorine tin oxide (FTO), Indium tin oxide (ITO), Indium zinc oxide (IZO), Aluminum zinc oxide (AZO), Gallium zinc oxide (GZO) and Zinc oxide (ZnO). The back electrode layer can be formed of a material selected from the group consisting of transparent conductive oxide (TCO), metal and combination thereof.

The transparent texture layer together with the predetermined area ratio of the laser scribing region can be configured to generate the light reflection or scattering when the incident light passes through the angular or arc surface of the transparent texture layer to further guide the incident light to concentrate on the photoelectric conversion active region so as to prevent the incident light from entering the invalid region of photoelectric conversion, thereby improving the photo-utilization of the incident light. On the other hand, the light path is increased due to the larger incident angle when the light reflection is reduced, thereby improving the photo-absorption and the photoelectric conversion efficiency of the silicon-based solar cell.

Although a preferred embodiment of the invention has been described for purposes of illustration, it is understood that various changes and modifications to the described embodiment can be carried out without departing from the scope and the spirit of the invention as disclosed in the appended claims.

### BRIEF DESCRIPTION OF DRAWINGS

The structure and the technical means adopted by the present invention to achieve the above and other objectives can be best understood by referring to the following detailed description of the preferred embodiments and the accompanying diagrams.

FIG. 1A is a sectional view that shows a substrate-type thin film solar cell having an angular surface of the transparent texture layer according to a first preferred embodiment of the invention.

FIG. 1B is a sectional view that shows the substrate-type thin film solar cell having an arc surface of the transparent texture layer according to the first preferred embodiment of the invention.

FIG. 2A is a sectional view that shows a superstrate-type thin film solar cell having an angular surface of the transparent texture layer according to a second preferred embodiment of the invention.

FIG. 2B is a sectional view that shows the superstrate-type thin film solar cell having an arc surface of the transparent texture layer according to the second preferred embodiment of the invention.

FIG. 3A is a top view that shows a wafer based silicon solar cell according to a third preferred embodiment of the invention.

FIG. 3B is a sectional view that shows the solar cell having wafers thereon with an angular surface of the transparent texture layer disposed on each wafer according to the third preferred embodiment of the invention.

FIG. 3C is a schematic view that shows the solar cell having wafers thereon according to the third preferred embodiment of the invention.

### DETAILED DESCRIPTION OF PREFERRED EMBODIMENTS

A solar cell thereof has been disclosed in the invention; wherein the principles of photoelectric conversion employed in solar cell may be easily comprehended by those of ordinary skill in relevant technical fields, and thus will not be further described hereafter. Meanwhile, it should be noted that the drawings referred to in the following paragraphs only serve the purpose of illustrating structures related to the characteristics of the disclosure, and are not necessarily drawn according to actual scales and sizes of the disclosed objects.

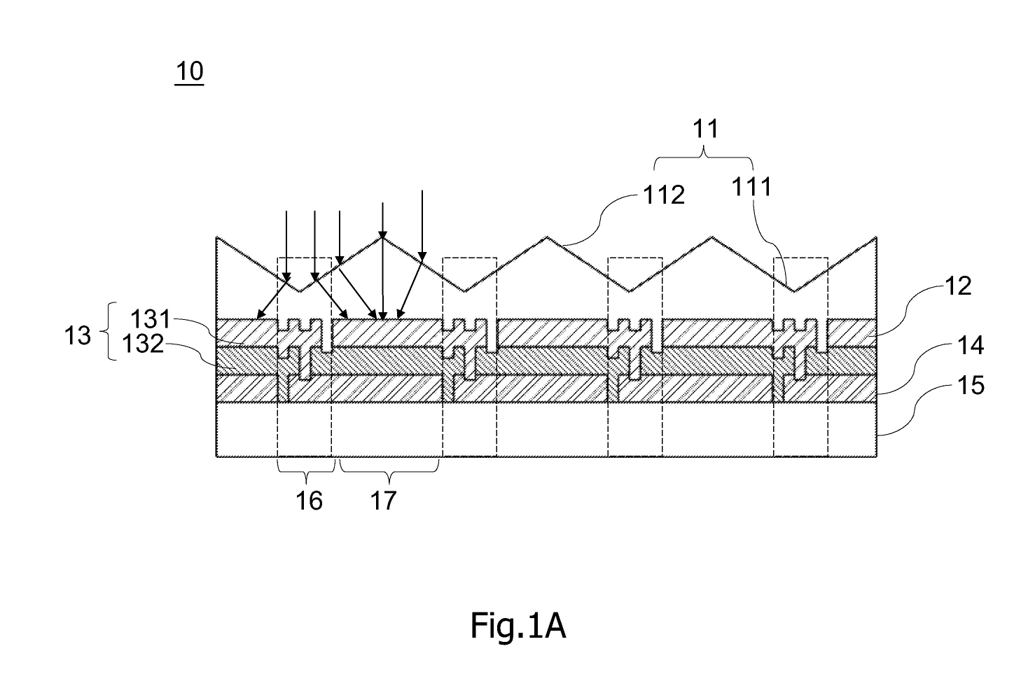

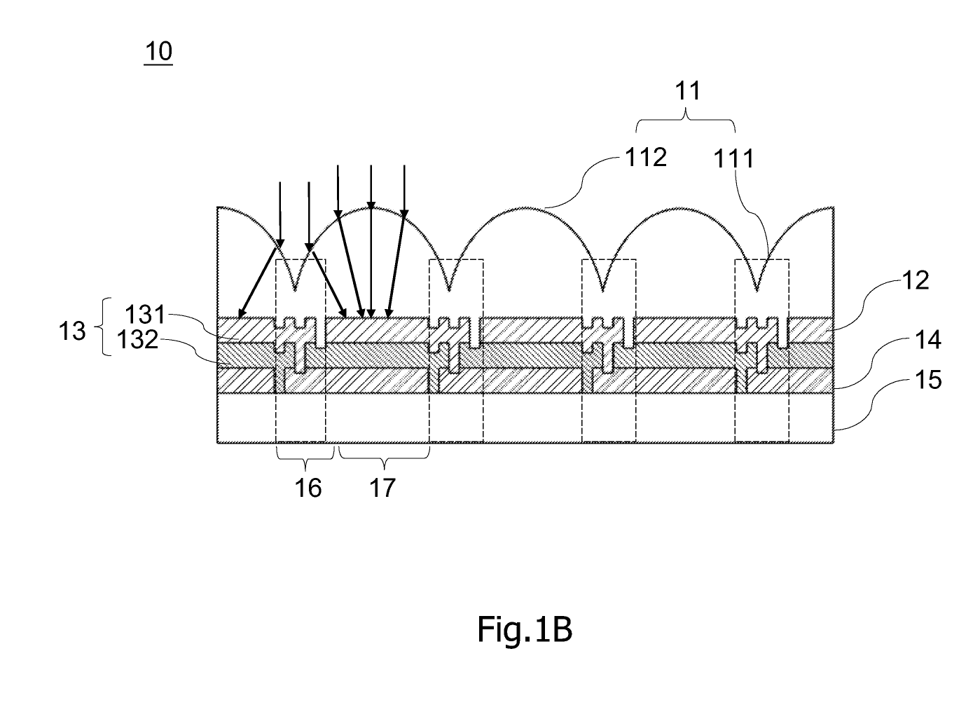

Refer to FIGS. 1A-1B, which are sectional views that show a solar cell having enhanced photo-utilization efficiency according to the first preferred embodiment of the invention. The preferred structure of the solar cell 10 is called a “substrate-type” thin film solar cell. The solar cell 10 with improved photo-utilization efficiency comprises a transparent texture layer 11, a transparent conductive layer 12, a photoelectric conversion layer 13, a back electrode layer 14 and a substrate 15 stacked in a sequence from an incident light side. For the sake of voltage improvement from the solar cell 10, the transparent conductive layer 12, the photoelectric conversion layer 13 and the back electrode layer 14 are being laser-scribed respectively during a module manufacturing so as to form serial-connected grooves disposed in each of the three layers. After the laser-scribed process, a laser scribing region 16 and a photoelectric conversion active region 17 are formed. The laser scribing region 16 is invalid for photoelectric conversion because most of the transparent conductive layer 12, the photoelectric conversion layer 13, and the back electrode layer 14 are removed to form the laser scribing region 16. Conversely, the photoelectric conversion active region 17 is valid for photoelectric conversion.

The transparent texture layer 11 has a concave portion 111 and a convex portion 112 where the concave portion 111 locates opposite to the laser scribing region 16, and the convex portion 112 is formed of a pyramid structure like an angular surface (shown in FIG. 1A) or a cylindrical structure like an arc surface (shown in FIG. 1B). When an incident light enters the convex portion 112 of the transparent texture layer 11, the incident light will be reflected or scattered along a reflected or scattered path (see arrow lines in FIGS. 1A-1B) so as to enter the photoelectric conversion active region 17 because the incident light is originally supposed to enter the laser scribing region 16, thereby guiding the incident light to concentrate on the photoelectric conversion active region 17, and further increasing the light path through the photoelectric conversion layer 13 as well. Besides, an area ratio of the laser scribing region 16 to the laser scribing region 16 plus the photoelectric conversion active region 17 has a predetermined value of between 0.08 and 0.17 so that the photo-absorption efficiency of the photoelectric conversion layer 13 can be improved significantly. Meanwhile, optical loss of the photoelectric conversion can be avoided because the probability of the incident light being guided to the laser scribing region 16 can be reduced significantly. Therefore, it can achieve the purpose of better photoelectric conversion in the photoelectric conversion layer 13. Besides, the structure of the convex portion 112 should not be limited to the afore-mentioned embodiment. Any other structures used in the convex portion 112 is applicable if it can concentrate the incident light on the photoelectric conversion active region 17 rather than on the laser scribing region 16. The transparent texture layer 11 can be a cover glass, or a transparent glass substrate that is selected from the group consisting of soda lime glass (SLG), low iron class and alkali free glass, or any other glass material having a refraction index value of between 1.5 and 1.9. The transparent texture layer 11 should not be limited to the afore-mentioned materials if it can guide the incident light to enter the solar cell 10 while it can concentrate the incident light on the photoelectric conversion active region 17.

On the other hand, the photoelectric conversion layer 13 comprises a buffer layer 131 and an absorption layer 132 so as to form a p-n type composite structure such that the p-n type composite structure can produce electron-hole pairs for photo-current due to photovoltaic effect. The absorption layer 132 is formed of a material selected from a group I-III-VI compounds such as Cu(In,Ga)Se2 or CIGS, CuInSe2 or CIS, or Ag(In,Ga)Se2 or AIGS. The buffer layer 131 is formed of a material selected from a group II-VI compounds such as cadmium sulfide (CdS), or zinc sulfide (ZnS). The substrate 15 is formed of a material selected from the group consisting of glass, quartz, transparent plastics, transparent polymer, flexible metals and flexible plastics.

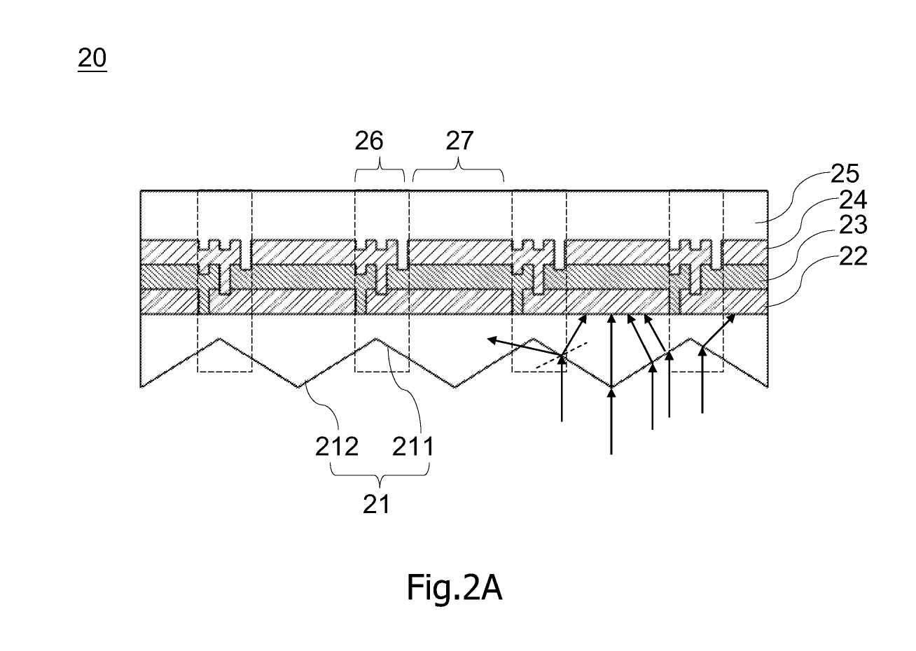

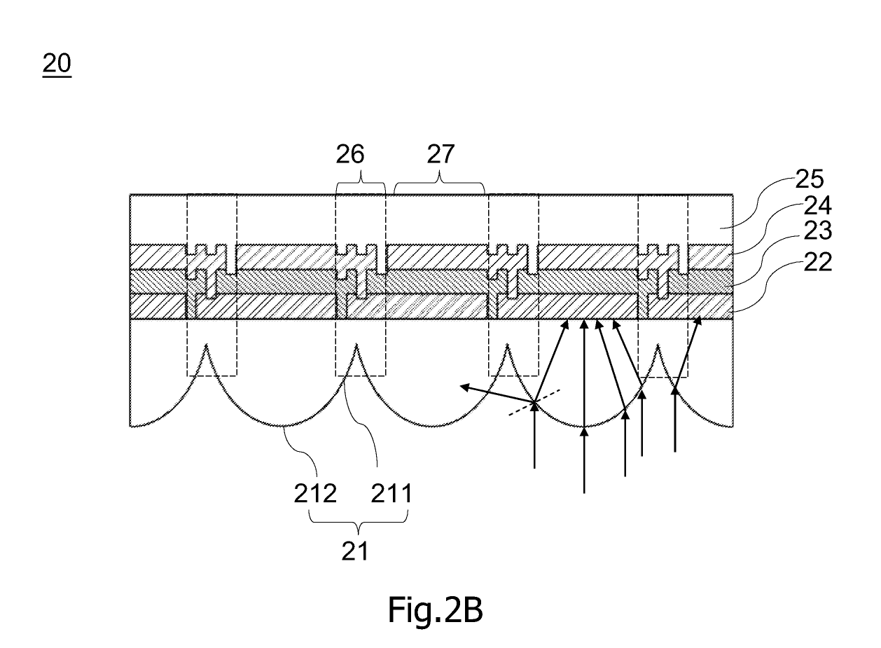

Please refer to FIGS. 2A-2B which are sectional views that show another solar cell having enhanced photo-utilization efficiency according to the second preferred embodiment of the invention. The preferred structure of the solar cell 20 is called a “superstrate-type” thin film solar cell. The solar cell 20 with improved photo-utilization efficiency comprises a transparent texture layer 21, a transparent conductive layer 22, a photoelectric conversion layer 23 and a back electrode layer 24 stacked in a sequence from an incident light side. A cover glass 25 can be disposed on the back electrode layer 24. Similarly to the first preferred embodiment, for the sake of voltage improvement from the solar cell 20, the transparent conductive layer 22, the photoelectric conversion layer 23 and the back electrode layer 24 are being laser-scribed respectively during a module manufacturing so as to form serial-connected grooves disposed in each of the three layers. After the laser-scribed process, a laser scribing region 26 and a photoelectric conversion active region 27 are formed. The laser scribing region 26 is invalid for photoelectric conversion because most of the transparent conductive layer 22, the photoelectric conversion layer 23 and the back electrode layer 24 are removed to form the laser scribing region 16. Conversely, the photoelectric conversion active region 27 is valid for photoelectric conversion.

The transparent texture layer 21 has a concave portion 211 and a convex portion 212 where the concave portion 211 locates opposite to the laser scribing region 26, and the convex portion 212 is formed of a pyramid structure like an angular surface (shown in FIG. 2A) or a cylindrical structure like an arc surface (shown in FIG. 2B). When an incident light enters the convex portion 212 of the transparent texture layer 21, the incident light will be reflected or scattered along a reflected or scattered path (see arrow lines in FIGS. 2A-2B) so as to enter the photoelectric conversion active region 27 because the incident light is originally supposed to enter the laser scribing region 26, thereby guiding the incident light to concentrate on the photoelectric conversion active region 27, and further increasing the light path through the photoelectric conversion layer 23 as well. Besides, an area ratio of the laser scribing region 26 to the laser scribing region 26 plus the photoelectric conversion active region 27 has a predetermined value of between 0.08 and 0.17 so that the photo-absorption efficiency of the photoelectric conversion layer 23 can be improved significantly. Meanwhile, optical loss of the photoelectric conversion can be avoided because the probability of the incident light being guided to the laser scribing region 26 can be reduced significantly. Therefore, it can achieve the purpose of better photoelectric conversion in the photoelectric conversion layer 23. Besides, the structure of the convex portion 212 should not be limited to the afore-mentioned embodiment. Any other structures used in the convex portion 212 is applicable if it can concentrate the incident light on the photoelectric conversion active region 27 rather than on the laser scribing region 26. The transparent texture layer 21 can be a cover glass, or a transparent glass substrate that is selected from the group consisting of soda lime glass (SLG), low iron class and alkali free glass, or any other glass material having a refraction index value of between 1.5 and 1.9. The transparent texture layer 21 should not be limited to the afore-mentioned materials if it can guide the incident light to enter the solar cell 20 while it can concentrate the incident light on the photoelectric conversion active region 27.

On the other hand, the photoelectric conversion layer 23 is formed of a material selected from one of amorphous silicon (a-Si), polycrystalline silicon (poly-Si), microcrystalline silicon (mc-Si) and microcrystalline silicon germanium (mc-SiGe), or a II-VI compound material selected from the group consisting of cadmium sulfide (CdS) and cadmium telluride (CdTe).

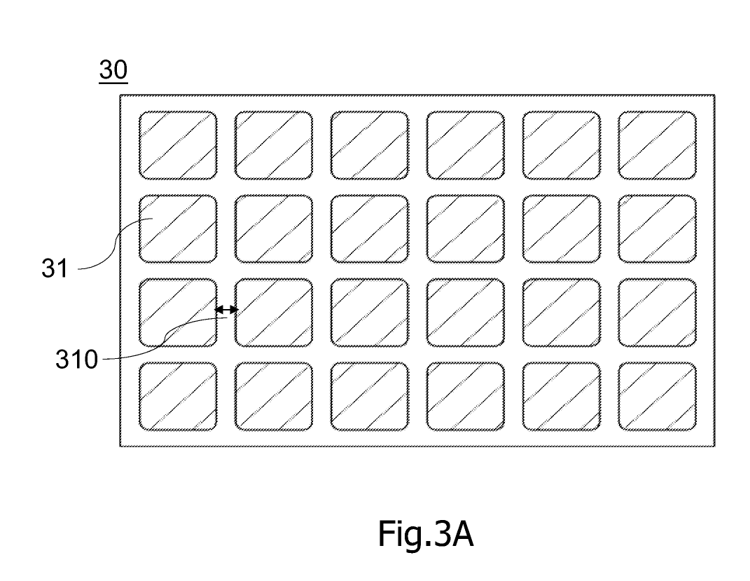

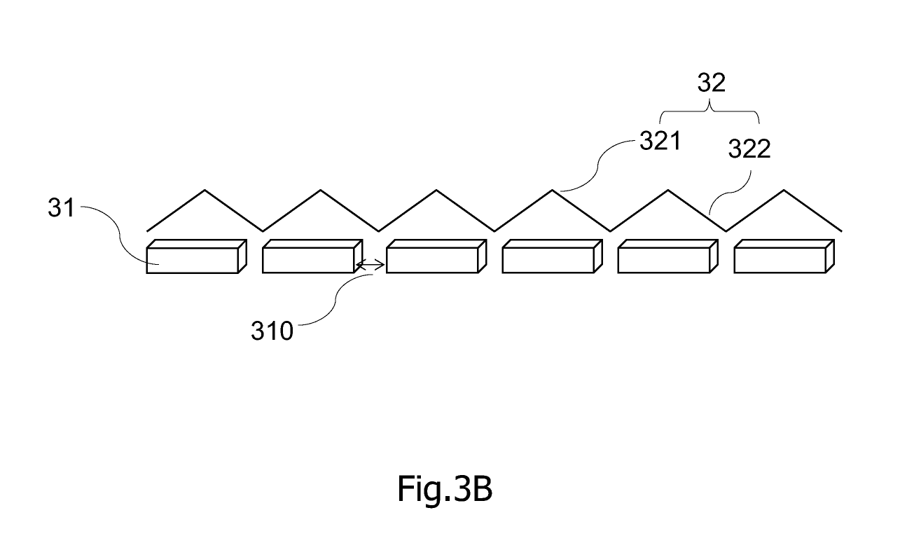

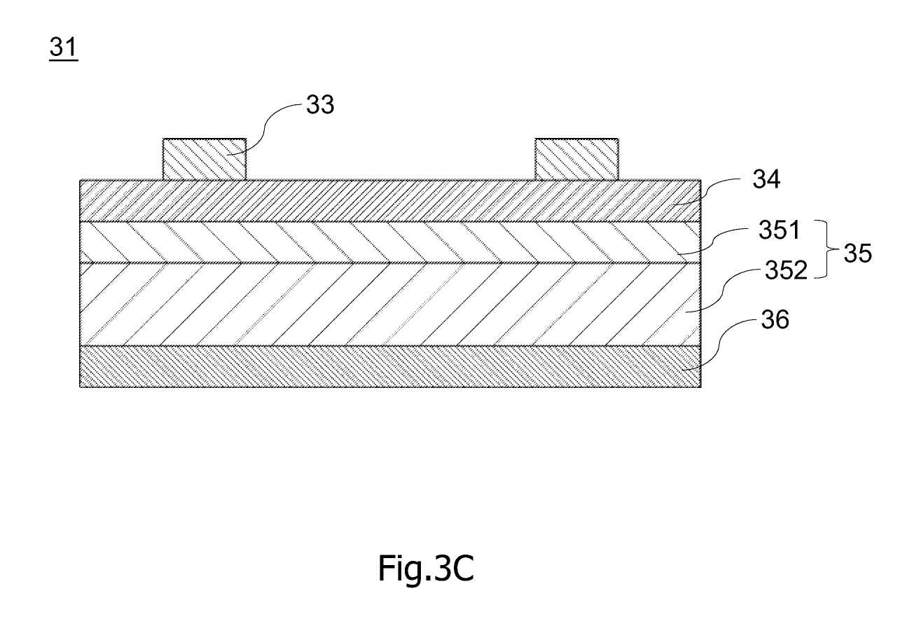

Please refer to FIGS. 3A-3C which are schematic views that shows a solar cell having enhanced photo-utilization efficiency according to the third preferred embodiment of the invention. The solar cell 30, which is a wafer-based silicon solar cell, comprises a plurality of silicon wafers 31 that are spaced therebetween. Each of the silicon wafers 31 comprise a front electrode layer 33, an anti-reflectance layer 34, a photoelectric conversion layer 35 and a back electrode layer 36 stacked in a sequence from an incident light side. Each of the silicon wafers 31 further comprises a transparent texture layer 32 formed on each wafer 31. A gap 310 is disposed between two adjacent wafers 31 so that the incident light may enter not only the wafers but also the gaps 310. However, the gaps 310 are invalid for photoelectric conversion, and thus the incident light passing through the gaps 310 cannot be utilized so as to cause a lower photo-utilization.

The transparent texture layer 32 has a concave portion 321 and a convex portion 322 that locates opposite to the gap 310 spaced between the plurality of silicon wafers 31. The convex portion 322 is formed of a pyramid structure like an angular surface (shown in FIG. 3B) or a cylindrical structure like an arc surface (not shown). When an incident light enters the convex portion 322 of the transparent texture layer 32, the incident light will be reflected or scattered along a reflected or scattered path (not shown) so as to enter the wafers 31 because the incident light is supposed to enter the gaps 310, thereby guiding the incident light to concentrate on the wafers 31 to further improve the efficiency of the photoelectric conversion layer 35 as well. Meanwhile, optical loss of the photoelectric conversion can be avoided because the probability of the incident light being guided to the gaps 310 can be reduced significantly. Therefore, it can achieve the purpose of better photoelectric conversion in the photoelectric conversion layer 35. Besides, the structure of the convex portion 322 should not be limited to the afore-mentioned embodiment. Any other structures used in the convex portion 322 is applicable if it can concentrate the incident light on the wafers 31 rather than on the gaps 310. The transparent texture layer 32 can be a transparent glass substrate that is selected from the group consisting of soda lime glass (SLG), low iron class and alkali free glass, or any other glass material having a refraction index value of between 1.5 and 1.9. The transparent texture layer 32 should not be limited to the afore-mentioned materials if it can guide the incident light to enter the solar cell 30 while it can concentrate the incident light on the wafers 31.

On the other hand, the front electrode layer 33 on the wafer 31 is formed with an EVA film (not shown) disposed on the front electrode layer 33. The anti-reflectance layer 34 is formed of a material such as magnesium fluoride (MgF2). The photoelectric conversion layer 35 comprises a n-type silicon layer 351 and a p-type silicon layer 352. Besides, the photoelectric conversion layer 35 is formed of a material selected from one of crystalline silicon (c-Si), amorphous silicon (a-Si), polycrystalline silicon (poly-Si), microcrystalline silicon (mc-Si) and microcrystalline silicon germanium (mc-SiGe).

Each layer of the foregoing solar cells 10,20,30 can be formed in a conventional method so as to stacked in such a sequence from an incident side. The conventional method may includes sputtering, atmosphere thermal chemical vapor deposition, low pressure chemical vapor deposition (LPCVD), electron cyclotron resonance chemical vapor deposition (ECR-CVD), D.C glow discharge, radio frequency glow discharge, hot filament chemical vapor deposition, and it should not be limited to the afore-mentioned methods. Besides, the transparent texture layers 11,21,32 can be scribed by a etcher machine, and it should not be limited to the afore-mentioned method.

In summary, the transparent texture layers 11,21,32 can be configured to guide the incident light to concentrate on the photoelectric conversion active region by means of reducing the reflection from different incident angles of the incident light while increasing the proceeding path of light passing through the photoelectric conversion layers 13,23,35, and increasing the number of the laser scribing regions 16,26 or wafers 31 while increasing the number of the convex portions 112,212,321, thereby improving reflecting and scattering of the incident light and further improving the photoelectric conversion efficiency of the solar cells 10,20,30. Although a preferred embodiment of the invention has been described for purposes of illustration, it is understood that various changes and modifications to the described embodiment can be carried out without departing from the scope and the spirit of the invention as disclosed in the appended claims.

What is claimed is:

1. A solar cell, which has a structure of improved photo-utilization efficiency, comprising a transparent texture layer, a transparent conductive layer, a photoelectric conversion layer, a back electrode layer and a substrate stacked in a sequence from an incident light side, wherein said transparent conductive layer, said photoelectric conversion layer and said back electrode layer are being scribed to form a laser scribing region and a photoelectric conversion active region, said transparent texture layer having a concave portion opposite to said laser scribing region so as to concentrate said incident light on said photoelectric conversion active region, an area ratio of said laser scribing region to said laser scribing region plus said photoelectric conversion active region having a value of between 0.08 and 0.17.

2. The solar cell of claim 1, wherein said transparent texture layer has an angular surface.

3. The solar cell of claim 1, wherein said transparent texture layer has an arc surface.

4. The solar cell of claim 1, wherein said transparent texture layer is a cover glass.

5. The solar cell of claim 1, wherein said transparent texture layer is a transparent glass substrate.

6. The solar cell of claim 1, wherein said photoelectric conversion layer comprises a buffer layer and an absorption layer to form a p-n type composite structure.

7. A solar cell, which has a structure of improved photo-utilization efficiency, comprising a transparent texture layer, a transparent conductive layer, a photoelectric conversion layer and a back electrode layer stacked in a sequence from an incident light side, wherein said transparent conductive layer, said photoelectric conversion layer and said back electrode layer are being scribed to form a laser scribing region and a photoelectric conversion active region, said transparent texture layer having a concave portion opposite to said laser scribing region so as to concentrate said incident light on said photoelectric conversion active region, an area ratio of said laser scribing region to said laser scribing region plus said photoelectric conversion active region having a value of between 0.08 and 0.17.

8. The solar cell of claim 7, wherein said transparent texture layer has an angular surface.

9. The solar cell of claim 7, wherein said transparent texture layer has an arc surface.

10. The solar cell of claim 7, wherein said transparent texture layer is a transparent glass substrate.

11. The solar cell of claim 7, wherein said photoelectric conversion layer has a material selected from the group consisting of amorphous silicon (a-Si), polycrystalline silicon (poly-Si), microcrystalline silicon (mc-Si) and microcrystalline silicon germanium (mc-SiGe).

12. The solar cell of claim 7, wherein said photoelectric conversion layer has a II-VI compound material selected from the group consisting of cadmium sulfide (CdS) and cadmium telluride (CdTe).

13. A solar cell, which has a structure of improved photo-utilization efficiency, comprising a plurality of silicon wafers spaced therebetween, each said silicon wafer comprising a front electrode layer, an anti-reflectance layer, a photoelectric conversion layer and a back electrode layer stacked in a sequence from an incident light side, wherein each said silicon wafer further comprises a transparent texture layer formed thereon, said transparent texture layer having a concave portion opposite to a gap spaced between said plurality of silicon wafers so as to concentrate said incident light on each said silicon wafer.

14. The solar cell of claim 13, wherein said transparent texture layer has an angular surface.

15. The solar cell of claim 13, wherein said transparent texture layer has an arc surface.

16. The solar cell of claim 13, wherein said front electrode layer of said transparent texture layer is formed with an EVA film thereon.

17. The solar cell of claim 13, wherein said transparent texture layer is a transparent glass substrate.

18. The solar cell of claim 13, wherein said photoelectric conversion layer has a material selected from the group consisting of crystalline silicon (c-Si), amorphous silicon (a-Si), polycrystalline silicon (poly-Si), microcrystalline silicon (mc-Si) and microcrystalline silicon germanium (mc-SiGe).
